(19) United States
(12) Patent Application Publication
(10) Pub. No.: US 2007/0279159 A1
(43) Pub. Date: Dec. 6, 2007

(54) Techniques to reduce circuit non-linear distortion

(76) Inventor: Heinz Georg Bachmann, Stow, MA (US)

Correspondence Address: James S. Finn;C/O William Tucker, 14431 Goliad Dr., Box # 8, Malakoff, TX, 75148, US

(21) Appl. No.: 11/446,473

(22) Filed: Jun. 2, 2006

(51) Int. Cl. H03J 3/06

(52) U.S. Cl. 334/15

(57) ABSTRACT

An embodiment of the present invention provides a method, comprising minimizing non-linear distortion effects in a circuit by applying tuning voltages within a predetermined voltage range to a plurality of oppositely oriented tunable capacitors within the circuit, thereby reducing the non-linear distortion effects. An embodiment of the present invention may further comprise applying an RF voltage within specified limits and wherein the predetermined voltage range may be determined so the combined capacitance of the plurality of tunable capacitors within the circuit remains essentially constant. Further, the predetermined voltage range may be derived by a CV curve that results in a constant total capacitance with no non-linear distortion.

### BACKGROUND OF THE INVENTION

Varactors are voltage tunable capacitors in which the capacitance is dependent on a voltage applied thereto. Although not limited in this respect, this property has applications in electrically tuning radio frequency (RF) circuits, such as filters, phase shifters, and so on. The most commonly used varactor is a semiconductor diode varactor, which has the advantages of high tunability and low tuning voltage, but suffers low Q, low power handling capability, and limited capacitance range. A new type of varactor is a ferroelectric varactor in which the capacitance is tuned by varying the dielectric constant of a ferroelectric material by changing the bias voltage. Ferroelectric varactors have high Q, high power handling capacity, and high capacitance range.

Difficulties, such as non-linear distortion effects like 3rd order intermodulation, arise in circuits that may use voltage tunable capacitors. Thus, a strong need exists for techniques to reduce circuit non-linear distortion.

### SUMMARY OF THE INVENTION

An embodiment of the present invention provides a method, comprising minimizing non-linear distortion effects in a circuit by applying tuning voltages within a predetermined voltage range to a plurality of oppositely oriented tunable capacitors within the circuit, thereby reducing the non-linear distortion effects. The present method may further comprise applying an RF voltage within specified limits. The predetermined voltage range may be determined so the combined capacitance of the plurality of tunable capacitors within the circuit remains essentially constant and the predetermined voltage range may be a derived CV curve that results in a constant total capacitance with no non-linear distortion.

In an embodiment of the present invention, the CV curve may be determined by selecting a desired tuning voltage (V_{T}) for a desired capacitance (C); selecting a maximum lower voltage range (V_{C1}) over which distortion-free operation is desired and with an upper edge of this range being (V_{T}); defining a CV curve between V_{C1} and V_{T}; and selecting or computing CV points therein with each consisting of a capacitance C_{L} and a tuning voltage V_{L,} with the value for C_{L} at V_{T} being 2×C. The present method may also further comprise selecting a tuning voltage (V_{T}) such that V_{T}>V_{L} and the CV curve may be such that for each value V_{L} and C_{L} there exists a corresponding point CV_{H} so that:

$${C}_{H} = \frac{1}{\frac{1}{C} - \frac{1}{{C}_{H}}} and {V}_{H} = ( 1 + \frac{{C}_{L}}{{C}_{H}} ) \cdot {V}_{T} - \frac{{C}_{L}}{{C}_{H}} \cdot {V}_{L}$$

### Although not limited in this respect, in an embodiment of the present invention, the present invention may provide a tunable matching network as well as a circuit that may be a tunable low pass filter circuit or a tunable band pass filter circuit.

Yet another embodiment of the present invention provides an apparatus, comprising a circuit capable of minimizing non-linear distortion effects by applying tuning voltages within a predetermined voltage range to a plurality of oppositely oriented tunable capacitors within the circuit, thereby reducing the non-linear distortion effects. The circuit of the apparatus is further capable of applying an RF voltage within specified limits and the predetermined voltage range may be determined so the combined capacitance of the plurality of tunable capacitors within the circuit remains essentially constant. Further, the predetermined voltage range may be selected from a derived CV curve that results in a constant total capacitance with no non-linear distortion.

Yet another embodiment of the present invention provides a circuit, comprising a plurality of oppositely oriented tunable capacitors capable of minimizing non-linear distortion effects within the circuit by applying tuning voltages within a predetermined voltage range to the tunable capacitors, thereby reducing the non-linear distortion effects. In one embodiment of the present circuit, the predetermined voltage range may be determined so the combined capacitance of the plurality of tunable capacitors within the circuit remains essentially constant

Still another embodiment of the present invention provides a low pass filter, comprising a circuit including a plurality of oppositely oriented tunable capacitors, wherein the circuit is capable of receiving from a voltage source tuning voltages within a predetermined voltage range that are chosen so that the combined capacitance of the plurality of tunable capacitors remains essentially constant, thereby reducing non-linear distortion effects. This low pass circuit may provide that the predetermined voltage range may be within a derived CV curve that results in a constant total capacitance with no non-linear distortion.

Yet another embodiment of the present invention provides a machine-accessible medium that provides instructions, which when accessed, cause a machine to perform operations comprising controlling tuning voltages within a predetermined voltage range that are provided to a plurality of oppositely oriented tunable capacitors within a circuit such that non-linear distortion effects in the circuit are reduced. The present machine-accessible medium may further comprise additional instructions to further control the application of RF voltage to the circuit that are within specified limits.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 illustrates an example of a voltage tunable capacitor circuit of one embodiment of the present invention;

FIG. 2 illustrates a circuit with oppositely oriented voltage tunable capacitors of one embodiment of the present invention;

FIG. 3 shows a straight-line capacitance vs. voltage curve of one embodiment of the present invention;

FIG. 4 graphically shows straight-line low voltages of one embodiment of the present invention;

FIG. 5 graphically depicts an adapted measured CV curve of one embodiment of the present invention; and

FIG. 6 shows a 2-Tone intermodulation product simulation of one embodiment of the present invention.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

An embodiment of the present invention provides a method to arrive at capacitance vs. tuning voltage (CV) functions in circuits with tunable capacitors (such as, but not limited to, Parascan® voltage tunable dielectric capacitors) so that, with certain tuning voltages applied, and with the applied RF voltage within specified limits, there are no non-linear distortion effects such as 3^{rd} order intermodulation.

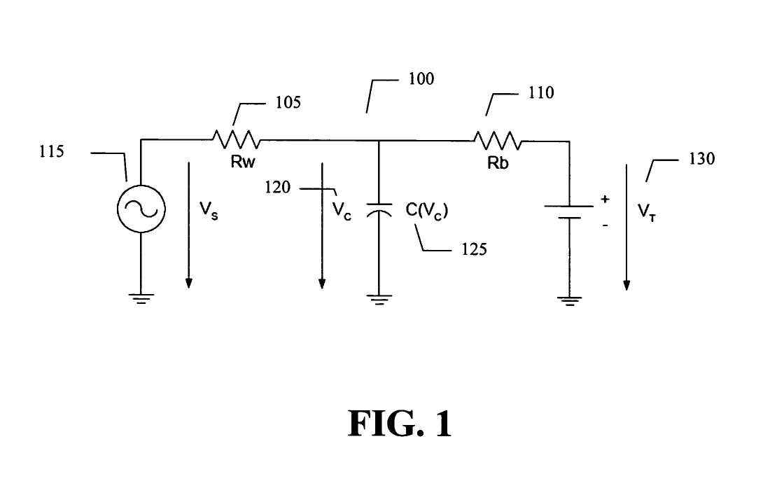

Turning now to the figures, FIG. 1, generally at 100, illustrates an example of a prior art voltage tunable capacitor circuit. This circuit 100 might be a tunable lowpass filter—although the present invention is limited in this respect. The capacitance of C is nominally determined by the tuning voltage V_{T} 130, yet it is a function of the total voltage V_{C} 120 applied to the capacitor. For very small voltages of V_{S} 115, C remains essentially constant. However, if the contribution of V_{S} 115 to V_{C} 120 is not much smaller than the specified range of V_{T} 130, this is not the case. C 125 changes so that V_{C} 120 is no longer what it would be over a fixed-value capacitor. This introduces non-linear distortions such as harmonics and, if V_{S} 115 consists of multiple tones, mixing products. Also, it is noted that Rb 110>>Rw 105.

Prior to the present invention, it was needed to design tunable capacitors that require tuning voltages much greater than the voltages of the signal for which the circuit is designed. Or another design option was to place many tunable capacitors in series so that the voltage over each individual capacitor is reduced resulting in less non linear distortion. As these solutions provided limited success, in an embodiment of the present invention is placed a plurality (such two in one embodiment of the present invention) of tunable capacitors in series in such a way that, when signal voltage is applied to the series capacitors, the capacitance of one capacitor increases while that of the other decreases, so that they partially compensate for each other's capacitance changes.

Circuits with high voltages are generally undesirable. Moreover, there are practical difficulties in generating such voltages cost-efficiently and power-efficiently in a small space, such as in mobile telephones, which may be one application of one embodiment of the present invention.

To arrive at a desired capacitance, the values of the individual capacitors must be greater than the desired total. For example, to arrive at a total capacitance of 1 pF using 4 capacitors in series, each capacitor must have a value of 4 pF. This has an adverse effect on dynamic behavior as the RC time constant increases and also requires increased current driving capacity in the tuning circuit.

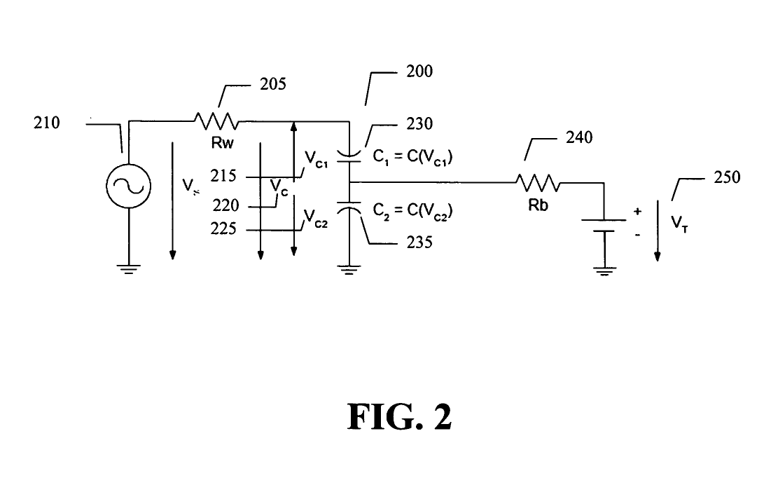

One solution implemented in one embodiment of the present invention is to replace a single voltage tunable capacitor with a plurality (such as two) oppositely oriented Parascan® tunable dielectric capacitors as shown in FIG. 2, generally at 200. In a two tunable capacitor embodiment, each capacitor (C₁ 230 and C₂ 235) has twice the nominal desired value. C(V) decreases monotonically with applied voltage, that is, C decreases as the voltage across the tunable capacitors increases, and vice versa. In Parascan® voltage tunable capacitors of the present invention, both capacitors 230 and 235, may have the same function C(V), or CV curve. Again, it is understood that the present invention is not limited to only Parascan® voltage tunable dielectric capacitors. Then, in the arrangement of FIG. 2, with only tuning voltage V_{T} 250 applied (V_{S} 210=0), both capacitors 230 and 235 assume equal values. As V_{S} 210 becomes positive, V_{C1} 215 decreases and C₁ 230 increases while at the same time V_{C2} 225 increases and so C₂ 225 decreases. When V_{S} 210 becomes negative, this is of course exactly reversed; we see a smaller C₁ 230 and a greater C₂ 235. The changes to the 2 voltage tunable capacitors thus occur in opposite directions and so in general at least partially cancel each other, resulting in less capacitance variation and thus less non-linear distortion than the circuit in FIG. 1. Rw is illustrated at 205.

When a plurality of Parascan® voltage tunable capacitors are used, in an embodiment of the present invention, a CV curve that minimizes non-linear distortions has been developed. The following algorithm creates a CV curve that results in a constant total capacitance C and thus no non-linear distortion when:

a. Operating at a specific tuning voltage. This tuning voltage can in principle be selected freely; and

b. The source voltage V_{S} remains within specific bounds. These bounds can also be selected to some extent, yet, although in an embodiment of the present invention, V_{S} must be low enough so that V_{T}>V_{C1}.

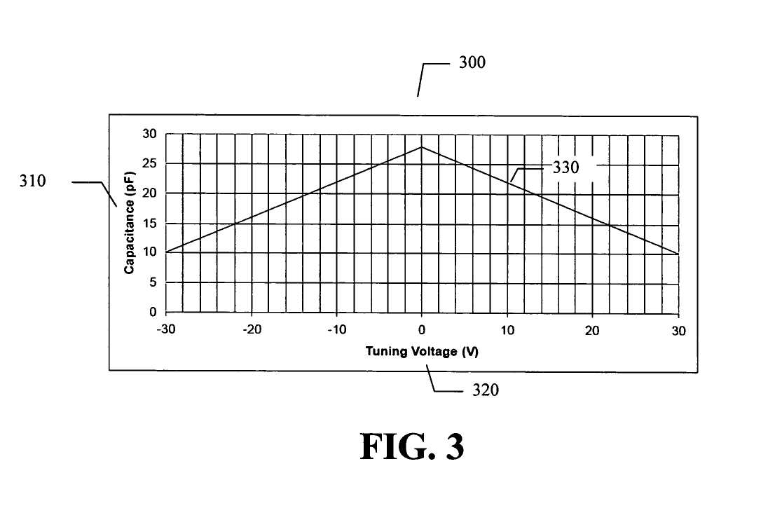

Turning now to FIG. 3, is shown generally at 300, a straight-line 330 capacitance 310 vs. voltage 320 curve of one embodiment of the present invention. This curve may not produce IMP-free performance but may be used as an example of how an existing curve may be modified to make it IMP-free. The following method may be used to create CV curves that result in no non-linear distortion at a certain bias voltages and a certain operating voltage range.

1. Select a desired capacitance C for distortion-free operation;

2. Select the desired tuning voltage V_{T} for capacitance C;

3. Select the maximum lower voltage range V_{C1} over which distortion-free operation is desired. The upper edge of this range must be V_{T}.

4. Define the CV curve within this range. Select or compute CV points therein, each consisting of a capacitance C_{L} and a tuning voltage V_{L}. The value for C_{L} at V_{T} must be 2×C.

5. For each capacitance value defined in 4 above, compute a capacitance value C_{H}.

The capacitance value may be calculated as follows, although it is understood that the following values and calculations are merely illustrative:

### Objective: Maintain C₁ and C₂ so that

$$\frac{1}{\frac{1}{{C}_{1}} + \frac{1}{{C}_{2}}} = C = Constant$$

### The CV curve C(V) must be such that, for all values V_{C1} and C(V_{C1}),

$$C ( {V}_{C 2} ) = \frac{1}{\frac{1}{C} - \frac{1}{C ( {V}_{C 1} )}} \qquad ( 1 )$$

For each value of C₁ and V_{C1} we can thus compute a value of C₂ and V_{C2} so that (1) is fulfilled. We compute each value of C₂ as

$${C}_{2} = \frac{1}{\frac{1}{C} - \frac{1}{{C}_{1}}} \qquad ( 2 )$$

### To compute V_{C2} we note that with complex voltages V_{S}=\hat{V}_{S}·e^{j·107 ·t} the complex voltage V_{C} will assume the form

V_{C}=\hat{V}_{C}·e^{j·ω·t+φ}

### Superposition

$$\begin{matrix}{V}_{C 1} = {V}_{T} - \frac{\frac{1}{j \cdot ω \cdot {C}_{1}}}{\frac{1}{j \cdot ω \cdot {C}_{1}} + \frac{1}{j \cdot ω \cdot {C}_{2}}} \cdot {V}_{C} = {V}_{T} - \frac{{C}_{2}}{{C}_{1} + {C}_{2}} \cdot {V}_{C} & ( 3 ) \\ {V}_{C 2} = {V}_{T} - \frac{\frac{1}{j \cdot ω \cdot {C}_{2}}}{\frac{1}{j \cdot ω \cdot {C}_{1}} + \frac{1}{j \cdot ω \cdot {C}_{2}}} \cdot {V}_{C} = {V}_{T} - \frac{{C}_{1}}{{C}_{1} + {C}_{2}} \cdot {V}_{C} & ( 4 )\end{matrix}$$

### Solving (3) for V_{C} and inserting in (4) we find

$${V}_{C 2} = ( 1 + \frac{{C}_{1}}{{C}_{2}} ) \cdot {V}_{T} - \frac{{C}_{1}}{{C}_{2}} \cdot {V}_{C 1} \qquad ( 5 )$$

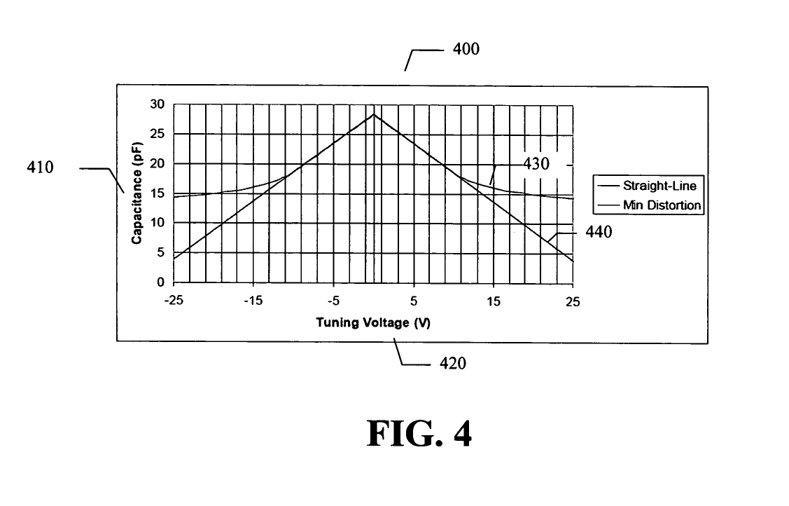

To continue with elaboration and exemplification without limitation, FIG. 4 at 400 graphically shows, in capacitance 410 vs. tuning voltage 420, straight-line low voltages 440 and min distortion 430 of one embodiment of the present invention. This illustrates a CV curve resulting in non-linear distortion for curves defined as follows: Operating Bias Voltage V_{T}—10V; Total Capacitance at V_{T}—9.3 pF; Capacitance at 0V V_{T}—14.2 pF; V_{C1} Range—0 to 10V; V_{C} Curve—in V_{C1} Range; Straight line VC Curve—in VC2 Range. These values were computed using the algorithm above and it is understood that the values used herein are for illustration and one embodiment and are but one of many possible curves that may be utilized in the present invention.

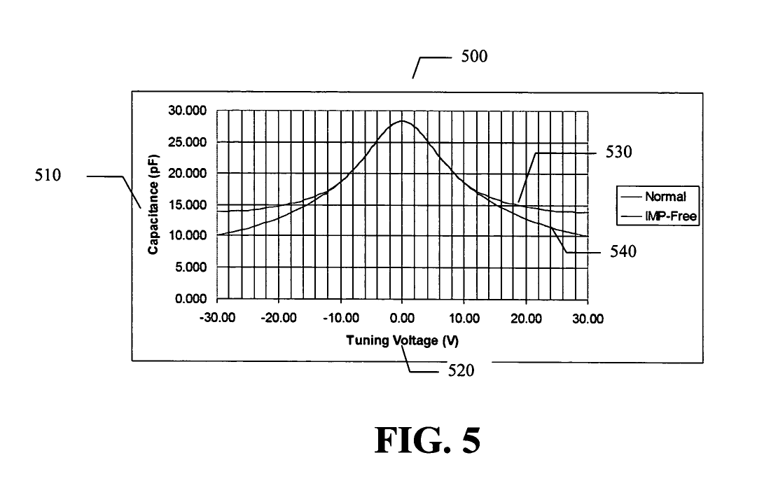

The curve in FIG. 4 may be difficult to attain in practice. Thus, the present invention provides modifying an existing curve to make it non-linear distortion free at a desired operating point. FIG. 5 shows such an example and provides at 500 a graph depicting an adapted measured CV curve one embodiment of the present invention. As can be seen, the result is not a straight line over the entire tuning range, but provides, in capacitance 510 vs. tuning voltage 520, normal curve 540 and IMP-Free curve 530. The normal curve 540 is a measured CV curve of an actual voltage tunable dielectric capacitor. The curve 530 represents a modification of this curve so that it is non-linear distortion free when biased with 10V while maintaining the original shape in the 0 to 10V range.

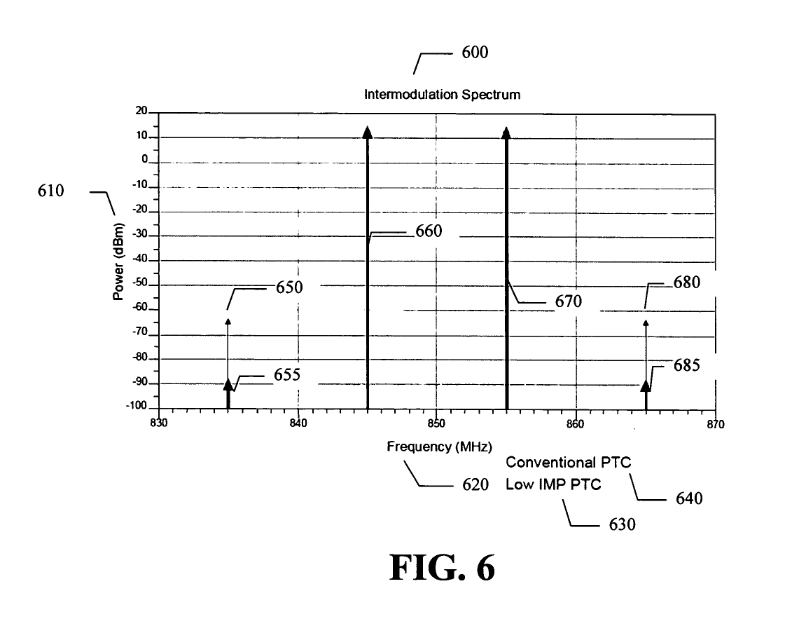

Turning now to FIG. 6, generally at 600 are the results in Power (dBm) 610 vs. Frequency (MHz) 620 of a 2-Tone intermodulation product simulation of one embodiment of the present invention. The resulting simulated 2-tone test illustrates that the IP3 improves from 53.5 dBm to 65.3 dBm, a 12 dB improvement. Conventional tunable capacitor power levels at 835 MHz are depicted at 650 in FIG. 6 and low IMP voltage tunable capacitor power levels are illustrated at 610. At 660 and 670 are both conventional and low IMP voltage tunable capacitor power levels at 845 MHz and 855 MHz respectively. The power at 865 MHz for conventional voltage tunable capacitors is shown at 680 while 685 depicts the power level of low IMP voltage tunable capacitors.

Throughout the aforementioned description, BST may be used as a tunable dielectric material that may be used in a tunable dielectric capacitor of the present invention. However, the assignee of the present invention, Paratek Microwave, Inc. has developed and continues to develop tunable dielectric materials that may be utilized in embodiments of the present invention and thus the present invention is not limited to using BST material. This family of tunable dielectric materials may be referred to as Parascan®.

The term Parascan® as used herein is a trademarked term indicating a tunable dielectric material developed by the assignee of the present invention. Parascan® tunable dielectric materials have been described in several patents. Barium strontium titanate (BaTiO3-SrTiO3), also referred to as BSTO, is used for its high dielectric constant (200-6,000) and large change in dielectric constant with applied voltage (25-75 percent with a field of 2 Volts/micron). Tunable dielectric materials including barium strontium titanate are disclosed in U.S. Pat. No. 5,312,790 to Sengupta, et al. entitled “Ceramic Ferroelectric Material”; U.S. Pat. No. 5,427,988 by Sengupta, et al. entitled “Ceramic Ferroelectric Composite Material-BSTO-MgO”; U.S. Pat. No. 5,486,491 to Sengupta, et al. entitled “Ceramic Ferroelectric Composite Material—BSTO—ZrO2”; U.S. Pat. No. 5,635,434 by Sengupta, et al. entitled “Ceramic Ferroelectric Composite Material-BSTO-Magnesium Based Compound”; U.S. Pat. No. 5,830,591 by Sengupta, et al. entitled “Multilayered Ferroelectric Composite Waveguides”; U.S. Pat. No. 5,846,893 by Sengupta, et al. entitled “Thin Film Ferroelectric Composites and Method of Making”; U.S. Pat. No. 5,766,697 by Sengupta, et al. entitled “Method of Making Thin Film Composites”; U.S. Pat. No. 5,693,429 by Sengupta, et al. entitled “Electronically Graded Multilayer Ferroelectric Composites”; U.S. Pat. No. 5,635,433 by Sengupta entitled “Ceramic Ferroelectric Composite Material BSTO—ZnO”; U.S. Pat. No. 6,074,971 by Chiu et al. entitled “Ceramic Ferroelectric Composite Materials with Enhanced Electronic Properties BSTO Mg Based Compound-Rare Earth Oxide”. These patents are incorporated herein by reference. The materials shown in these patents, especially BSTO—MgO composites, show low dielectric loss and high tunability. Tunability is defined as the fractional change in the dielectric constant with applied voltage.

Barium strontium titanate of the formula BaxSr1-xTiO3 is a preferred electronically tunable dielectric material due to its favorable tuning characteristics, low Curie temperatures and low microwave loss properties. In the formula BaxSr1-xTiO3, x can be any value from 0 to 1, preferably from about 0.15 to about 0.6. More preferably, x is from 0.3 to 0.6.

Other electronically tunable dielectric materials may be used partially or entirely in place of barium strontium titanate. An example is BaxCa1-xTiO3, where x is in a range from about 0.2 to about 0.8, preferably from about 0.4 to about 0.6. Additional electronically tunable ferroelectrics include PbxZr1-xTiO3 (PZT) where x ranges from about 0.0 to about 1.0, PbxZr1-xSrTiO3 where x ranges from about 0.05 to about 0.4, KTaxNb1-xO3 where x ranges from about 0.0 to about 1.0, lead lanthanum zirconium titanate (PLZT), PbTiO3, BaCaZrTiO3, NaNO3, KNbO3, LiNbO3, LiTaO3, PbNb2O6, PbTa2O6, KSr(NbO3) and NaBa2(NbO3)5KH2PO4, and mixtures and compositions thereof. Also, these materials can be combined with low loss dielectric materials, such as magnesium oxide (MgO), aluminum oxide (Al2O3), and zirconium oxide (ZrO2), and/or with additional doping elements, such as manganese (MN), iron (Fe), and tungsten (W), or with other alkali earth metal oxides (i.e. calcium oxide, etc.), transition metal oxides, silicates, niobates, tantalates, aluminates, zirconnates, and titanates to further reduce the dielectric loss.

In addition, the following U.S. patents and patent Applications, assigned to the assignee of this application, disclose additional examples of tunable dielectric materials: U.S. Pat. No. 6,514,895, entitled “Electronically Tunable Ceramic Materials Including Tunable Dielectric and Metal Silicate Phases”; U.S. Pat. No. 6,774,077, entitled “Electronically Tunable, Low-Loss Ceramic Materials Including a Tunable Dielectric Phase and Multiple Metal Oxide Phases”; U.S. Pat. No. 6,737,179 filed Jun. 15, 2001, entitled “Electronically Tunable Dielectric Composite Thick Films And Methods Of Making Same; U.S. Pat. No. 6,617,062 entitled “Strain-Relieved Tunable Dielectric Thin Films”; U.S. Pat. No. 6,905,989, filed May 31, 2002, entitled “Tunable Dielectric Compositions Including Low Loss Glass”; U.S. patent application Ser. No. 10/991,924, filed Nov. 18, 2004, entitled “Tunable Low Loss Material Compositions and Methods of Manufacture and Use Therefore” These patents and patent applications are incorporated herein by reference.

The tunable dielectric materials can also be combined with one or more non-tunable dielectric materials. The non-tunable phase(s) may include MgO, MgAl2O4, MgTiO3, Mg2SiO4, CaSiO3, MgSrZrTiO6, CaTiO3, Al2O3, SiO2 and/or other metal silicates such as BaSiO3 and SrSiO3. The non-tunable dielectric phases may be any combination of the above, e.g., MgO combined with MgTiO3, MgO combined with MgSrZrTiO6, MgO combined with Mg2SiO4, MgO combined with Mg2SiO4, Mg2SiO4 combined with CaTiO3 and the like.

Additional minor additives in amounts of from about 0.1 to about 5 weight percent can be added to the composites to additionally improve the electronic properties of the films. These minor additives include oxides such as zirconnates, tannates, rare earths, niobates and tantalates. For example, the minor additives may include CaZrO3, BaZrO3, SrZrO3, BaSnO3, CaSnO3, MgSnO3, Bi2O3/2SnO2, Nd2O3, Pr7O11, Yb2O3, Ho2O3, La2O3, MgNb2O6, SrNb2O6, BaNb2O6, MgTa2O6, BaTa2O6 and Ta2O3.

Films of tunable dielectric composites may comprise Ba1-xSrxTiO3, where x is from 0.3 to 0.7 in combination with at least one non-tunable dielectric phase selected from MgO, MgTiO3, MgZrO3, MgSrZrTiO6, Mg2SiO4, CaSiO3, MgAl2O4, CaTiO3, Al2O3, SiO2, more of these components in quantities from 0.25 weight percent to 80 weight percent with BSTO weight ratios of 99.75 weight percent to 20 weight percent.

The electronically tunable materials may also include at least one metal silicate phase. The metal silicates may include metals from Group 2A of the Periodic Table, i.e., Be, Mg, Ca, Sr, Ba and Ra, preferably Mg, Ca, Sr and Ba. Preferred metal silicates include Mg2SiO4, CaSiO3, BaSiO3 and SrSiO3. In addition to Group 2A metals, the present metal silicates may include metals from Group 1A, i.e., Li, Na, K, Rb, Cs and Fr, preferably Li, Na and K. For example, such metal silicates may include sodium silicates such as Na2SiO3 and NaSiO3-5H2O, and lithium-containing silicates such as LiAlSiO4, Li2SiO3 and Li4SiO4. Metals from Groups 3A, 4A and some transition metals of the Periodic Table may also be suitable constituents of the metal silicate phase. Additional metal silicates may include Al2Si2O7, ZrSiO4, KalSi3O8, NaAlSi3O8, CaAl2Si2O8, CaMgSi2O6, BaTiSi3O9 and Zn2SiO4. The above tunable materials can be tuned at room temperature by controlling an electric field that is applied across the materials.

In addition to the electronically tunable dielectric phase, the electronically tunable materials can include at least two additional metal oxide phases. The additional metal oxides may include metals from Group 2A of the Periodic Table, i.e., Mg, Ca, Sr, Ba, Be and Ra, preferably Mg, Ca, Sr and Ba. The additional metal oxides may also include metals from Group 1A, i.e., Li, Na, K, Rb, Cs and Fr, preferably Li, Na and K. Metals from other Groups of the Periodic Table may also be suitable constituents of the metal oxide phases. For example, refractory metals such as Ti, V, Cr, Mn, Zr, Nb, Mo, Hf, Ta and W may be used. Furthermore, metals such as Al, Si, Sn, Pb and Bi may be used. In addition, the metal oxide phases may comprise rare earth metals such as Sc, Y, La, Ce, Pr, Nd and the like.

The additional metal oxides may include, for example, zirconnates, silicates, titanates, aluminates, stannates, niobates, tantalates and rare earth oxides. Preferred additional metal oxides include Mg2SiO4, MgO, CaTiO3, MgZrSrTiO6, MgTiO3, MgAl2O4, WO3, SnTiO4, ZrTiO4, CaSiO3, CaSnO3, CaWO4, CaZrO3, MgTa2O6, MgZrO3, MnO2, PbO, Bi2O3 and La2O3. Particularly preferred additional metal oxides include Mg2SiO4, MgO, CaTiO3, MgZrSrTiO6, MgTiO3, MgAl2O4, MgTa2O6 and MgZrO3.

The additional metal oxide phases are typically present in total amounts of from about 1 to about 80 weight percent of the material, preferably from about 3 to about 65 weight percent, and more preferably from about 5 to about 60 weight percent. In one preferred embodiment, the additional metal oxides comprise from about 10 to about 50 total weight percent of the material. The individual amount of each additional metal oxide may be adjusted to provide the desired properties. Where two additional metal oxides are used, their weight ratios may vary, for example, from about 1:100 to about 100:1, typically from about 1:10 to about 10:1 or from about 1:5 to about 5:1. Although metal oxides in total amounts of from 1 to 80 weight percent are typically used, smaller additive amounts of from 0.01 to 1 weight percent may be used for some applications.

The additional metal oxide phases can include at least two Mg-containing compounds. In addition to the multiple Mg-containing compounds, the material may optionally include Mg-free compounds, for example, oxides of metals selected from Si, Ca, Zr, Ti, Al and/or rare earths.

While the present invention has been described in terms of what are at present believed to be its preferred embodiments, those skilled in the art will recognize that various modifications to the disclose embodiments can be made without departing from the scope of the invention as defined by the following claims.

What is claimed is:

1. A method, comprising:
minimizing non-linear distortion effects in a circuit by applying tuning voltages within a predetermined voltage range to a plurality of oppositely oriented tunable capacitors within said circuit, thereby reducing said non-linear distortion effects.

2. The method of claim 1, further comprising applying an RF voltage within specified limits.

3. The method of claim 1, wherein said predetermined voltage range is determined so the combined capacitance of said plurality of tunable capacitors within said circuit remains essentially constant

4. The method of claim 1, wherein said predetermined voltage range is with a derived CV curve that results in a constant total capacitance with no non-linear distortion.

5. The method of claim 4, wherein said CV curve is determined by:
selecting a desired tuning voltage (V_{T}) for a desired capacitance (C);
selecting a maximum lower voltage range (V_{C1}) over which distortion-free operation is desired and with an upper edge of this range being (V_{T});
defining a CV curve within V_{T};
selecting or computing CV points therein with each consisting of a capacitance C_{L} and a tuning voltage V_{L,} with the value for C_{L} at V_{T} being 2×C.

6. The method of claim 5, further comprising selecting a tuning voltage (T_{S}) such that V_{T}>V_{C1}.

7. The method of claim 5, wherein said CV curve is such that for all values V_{C1} and C(V_{C1}):
$$C ( {V}_{C 2} ) = \frac{1}{\frac{1}{C} - \frac{1}{C ( {V}_{C 1} )}}$$

8. The method of claim 1, wherein said circuit is a tunable low pass filter circuit.

9. The method of claim 1, wherein said circuit is a tunable band pass filter circuit.

10. An apparatus, comprising:
a circuit capable of minimizing non-linear distortion effects by applying tuning voltages within a predetermined voltage range to a plurality of oppositely oriented tunable capacitors within said circuit, thereby reducing said non-linear distortion effects.

11. The apparatus of claim 10, wherein said circuit is further capable of applying an RF voltage within specified limits.

12. The apparatus of claim 10, wherein said predetermined voltage range is determined so the combined capacitance of said plurality of tunable capacitors within said circuit remains essentially constant

13. The apparatus of claim 10, wherein said predetermined voltage range is with a derived CV curve that results in a constant total capacitance with no non-linear distortion.

14. The apparatus of claim 13, wherein said CV curve is determined by:
selecting a desired tuning voltage (V_{T}) for a desired capacitance (C);
selecting a maximum lower voltage range (V_{C1}) over which distortion-free operation is desired and with an upper edge of this range being (V_{T});
defining a CV curve within V_{T}; and
selecting or computing CV points therein with each consisting of a capacitance C_{L} and a tuning voltage V_{L,} with the value for C_{L} at V_{T} being 2×C.

15. The apparatus of claim 14, further comprising selecting a tuning voltage (T_{S}) such that V_{T}>V_{C1}.

16. The apparatus of claim 14, wherein said CV curve is such that for all values V_{C1} and C(V_{C1}):
$$C ( {V}_{C 2} ) = \frac{1}{\frac{1}{C} - \frac{1}{C ( {V}_{C 1} )}}$$

17. The apparatus of claim 10, wherein said apparatus is a tunable low pass filter.

18. The apparatus of claim 10, wherein said apparatus is a tunable band pass filter.

19. An circuit, comprising:
a plurality of oppositely oriented tunable capacitors capable of minimizing non-linear distortion effects within said circuit by applying tuning voltages within a predetermined voltage range to said tunable capacitors, thereby reducing said non-linear distortion effects.

20. The circuit of claim 19, wherein said predetermined voltage range is determined so the combined capacitance of said plurality of tunable capacitors within said circuit remains essentially constant

21. The circuit of claim 19, wherein said predetermined voltage range is within a derived CV curve that results in a constant total capacitance with no non-linear distortion.

22. The circuit of claim 19, wherein said CV curve is determined by:
selecting a desired tuning voltage (V_{T}) for a desired capacitance (C);
selecting a maximum lower voltage range (V_{C1}) over which distortion-free operation is desired and with an upper edge of this range being (V_{T});
defining a CV curve within V_{T}; and
selecting or computing CV points therein with each consisting of a capacitance C_{L} and a tuning voltage V_{L,} with the value for C_{L} at V_{T} being 2×C.

23. The circuit of claim 14, further comprising selecting a tuning voltage (T_{S}) such that V_{T}>V_{C1}.

24. The circuit of claim 19, wherein said CV curve is such that for all values V_{C1} and C(V_{C1}):
$$C ( {V}_{C 2} ) = \frac{1}{\frac{1}{C} - \frac{1}{C ( {V}_{C 1} )}}$$

25. A low pass filter, comprising:
a circuit including a plurality of oppositely oriented tunable capacitors, wherein said circuit is capable of receiving from a voltage source tuning voltages within a predetermined voltage range that are chosen so that the combined capacitance of said plurality of tunable capacitors remains essentially constant, thereby reducing non-linear distortion effects.

26. The low pass filter of claim 25, wherein said predetermined voltage range is within a derived CV curve that results in a constant total capacitance with no non-linear distortion.

27. The low pass filter of claim 25, wherein said CV curve is determined by:
selecting a desired tuning voltage (V_{T}) for a desired capacitance (C);
selecting a maximum lower voltage range (V_{C1}) over which distortion-free operation is desired and with an upper edge of this range being (V_{T});
defining a CV curve within V_{T}; and
selecting or computing CV points therein with each consisting of a capacitance C_{L} and a tuning voltage V_{L,} with the value for C_{L} at V_{T} being 2×C.

28. The low pass filter of claim 25, further comprising selecting a tuning voltage (T_{S}) such that V_{T}>V_{C1}.

29. A machine-accessible medium that provides instructions, which when accessed, cause a machine to perform operations comprising:
controlling tuning voltages within a predetermined voltage range that are provided to a plurality of oppositely oriented tunable capacitors within a circuit such that non-linear distortion effects in said circuit are reduced.

30. The machine-accessible medium of claim 29, further comprising further instructions to further control the application of RF voltage to said circuit that are within specified limits.

31. The machine-accessible medium of claim 29, wherein said predetermined voltage range is determined so the combined capacitance of said plurality of tunable capacitors within said circuit remains essentially constant

32. The machine-accessible medium of claim 29, wherein said predetermined voltage range is with a derived CV curve that results in a constant total capacitance with no non-linear distortion.

33. The machine-accessible medium of claim 32, wherein said CV curve is determined by:
selecting a desired tuning voltage (V_{T}) for a desired capacitance (C);
selecting a maximum lower voltage range (V_{C1}) over which distortion-free operation is desired and with an upper edge of this range being (V_{T});
defining a CV curve within V_{T};
selecting or computing CV points therein with each consisting of a capacitance C_{L} and a tuning voltage V_{L,} with the value for C_{L} at V_{T} being 2×C.

34. A tunable matching networks, comprising:
at least one circuit with a plurality of oppositely oriented tunable capacitors capable of minimizing non-linear distortion effects within said circuit by applying tuning voltages within a predetermined voltage range to said tunable capacitors, thereby reducing said non-linear distortion effects.

35. The tunable matching networks of claim 4 wherein said predetermined voltage range is determined so the combined capacitance of said plurality of tunable capacitors within said circuit remains essentially constant

36. The tunable matching networks 34, wherein said predetermined voltage range is within a derived CV curve that results in a constant total capacitance with no non-linear distortion.

37. The tunable matching networks of claim 34, wherein said CV curve is determined by:
selecting a desired tuning voltage (V_{T}) for a desired capacitance (C);
selecting a maximum lower voltage range (V_{C1}) over which distortion-free operation is desired and with an upper edge of this range being (V_{T});
defining a CV curve within V_{T}; and
selecting or computing CV points therein with each consisting of a capacitance C_{L} and a tuning voltage V_{L,} with the value for C_{L} at V_{T} being 2×C.

38. The circuit of claim 34, wherein said CV curve is such that for all values V_{C1} and C(V_{C1}):
$$C ( {V}_{C 2} ) = \frac{1}{\frac{1}{C} - \frac{1}{C ( {V}_{C 1} )}}$$
